(19) United States
(12) Patent Application Publication
(10) Pub. No.: US 2013/0250522 A1
(43) Pub. Date: Sep. 26, 2013

(54) HEAT SINK PROFILE FOR INTERFACE TO THERMALLY CONDUCTIVE MATERIAL

(71) Applicants: Russell J. Maxfield, Riverton, UT (US); Steven D. Bandis, West Jordan, UT (US); Veselin Kolev, Cupertino, CA (US); Ivan P. Mollov, Mountain View, CA (US)

(72) Inventors: Russell J. Maxfield, Riverton, UT (US); Steven D. Bandis, West Jordan, UT (US); Veselin Kolev, Cupertino, CA (US); Ivan P. Mollov, Mountain View, CA (US)

(73) Assignee: Varian Medical Systems, Inc., Palo Alto, CA (US)

(21) Appl. No.: 13/426,875

(22) Filed: Mar. 22, 2012

(51) Int. Cl. H05K 7/20; B23P 15/26; F28F 7/00

(52) U.S. Cl. 361/718; 165/185; 29/890.03

(57) ABSTRACT

A heat sink employs a scalloped surface profile to facilitate interface to thermally conductive materials. The scalloped surface profile reduces the surface area initially as the thermally conductive material is compressed for assembly. The reduced surface area allows the required compression force to be decreased, which helps reduce the risk of damages to the heat generating devices due to excessive force. The scalloped surface profile increases the final surface area in contact with the thermally conductive material after assembly. The increased final surface area helps improve the transfer capacities of the heat sink.

### BACKGROUND

This disclosure relates in general to methods and devices for heat transfer, and in particular, to heat sinks having surface profiles for interface to thermally conductive materials.

Heat sinks are known and commonly used to facilitate transfer of heat from heat generating devices to an external environment. Typically, a heat sink engages a heat generating device to absorb heat from the device and then dissipates the absorbed heat to the ambient environment. A thermally conductive material is typically used as an interface between the heat sink and the heat generating device to fill the gap that may exist and to facilitate heat transfer from the heat generating device to the heat sink. During assembly, the thermally conductive material is sandwiched between the heat generating device and the heat sink and compressed to bring in contact with the heat sink and the heat generating device.

Conventionally, the surface of the heat sink that comes in contact with the thermally conductive material is very flat. This creates a very high surface area, and thus requires a relatively large initial compression force to bring the heat generating device and the heat sink in contact with the thermally conductive material for assembly. A large compression force for assembly increases the risk of causing damages to the device or fragile components of the device.

There is therefore a need for a heat sink that has a surface profile for interface to thermally conductive materials to reduce the risk of causing damages to the heat generating devices. There is further a need for a heat sink that can provide improved heat transfer capacity.

### SUMMARY

Heat sinks having a scalloped surface for interface to thermally conductive materials are provided. Devices and methods for assembling devices incorporating the heat sinks are also provided. Other embodiments are described further herein.

### BRIEF DESCRIPTION OF THE DRAWINGS

These and various other features and advantages will become better understood upon reading of the following detailed description in conjunction with the accompanying drawings and the appended claims provided below, where:

FIG. 1 is an exploded view of an assembly including a heat sink, a heat generating device, and a thermally conductive material in accordance with some embodiments of the disclosure;

FIG. 2 illustrates an exemplary heat sink in a perspective and a cross-sectional view in accordance with some embodiments of the disclosure;

FIG. 3 illustrates another exemplary heat sink in a perspective and a cross-sectional view in accordance with some embodiments of the disclosure;

FIG. 4 illustrates a further exemplary heat sink in a perspective and a cross-sectional view in accordance with some embodiments of the disclosure; and

FIG. 5 illustrates an exemplary heat sink which is an integral part of an enclosure in accordance with some embodiments of the disclosure.

### DETAILED DESCRIPTION OF EMBODIMENTS

Various embodiments of heat sinks and devices or assemblies incorporating the heat sinks are described. It should be noted that these particular embodiments are for illustration purpose and not intended to be limiting since the scope of the invention will be defined by the appended claims, along with the full scope of equivalents to which such claims are entitled.

Various relative terms such as “above,” “under,” “upper,” “over,” “on,” top,” “bottom,” “higher,” and “lower” etc. may be used to facilitate description of various embodiments. The relative terms are defined with respect to a conventional orientation of a structure and do not necessarily represent an actual orientation of the structure in manufacture or use. The following detailed description is, therefore, not to be taken in a limiting sense. As used in the description and appended claims, the singular forms of “a,” “an,” and “the” include plural references unless the context clearly dictates otherwise.

As used herein, the term “scalloped surface” refers to a surface that has concave surface portions and non-concave surface portions. For example, a surface may have a plurality of recesses, providing for a plurality of concave surface portions over the recesses and a plurality of non-concave surface portions connecting adjacent concave surface portions. In some preferred embodiments, some concave surface portions have a cross-sectional shape of an arc, a square, a rectangle, a triangle, a trapezoid, a curve, or any other regular or irregular shape. In some embodiments, the non-concave surface portions are in a substantially same imaginary plane. In some embodiments, some non-concave surface portions are narrow or proximate one-dimensional lines as compared to adjacent concave surface portions. In some embodiments, the concave surface portions may contain additional dents, recesses, or smaller concave portions. In some embodiments, the non-concave surface portions may be flat or curved. The non-concave surface portions may also contain additional dents, recesses, or smaller concave portions to maximize surface area for thermal conduction.

The present disclosure provides a heat sink that has a scalloped surface profile to facilitate interface to thermally conductive materials. The scalloped surface profile reduces the surface area initially as the thermally conductive material is compressed for assembly. This reduced surface area allows the required compression force to be decreased, which helps reduce the risk of damages to the heat generating devices due to excessive force. Then, while compressing, the thermally conductive material may flow over the scalloped surface until the thermally conductive material is in contact with the entire scalloped surface. Because of the scalloped surface profile, the final surface area in contact with the thermally conductive material is increased over a flat surface, and as a result, the heat transfer capacities of the heat sink are improved.

In some embodiments, provided is a heat sink that comprises a scalloped surface configured to interface a thermally conductive material. The scalloped surface may include a plurality of recesses, providing for a plurality of concave surface portions over the recesses, and a plurality of non-concave surface portions connecting adjacent concave surface portions. The non-concave surface portions may be designed to facilitate initial compression with a thermally conductive material for assembly. The concave surface portions may be designed for allowing the thermally conductive material to flow over while being compressed and fill in the entire recesses.

In some embodiments, the recesses on the scalloped surface may be elongate grooves substantially in parallel, providing for a plurality of elongate concave surface portions and a plurality of elongate non-concave surface portions, alternating each other. The elongate non-concave surface portions may be narrow and in some embodiments may be proximate one-dimensional as compared to the elongate concave surface portions. The narrow non-concave surface portions may facilitate assembly of the heat sink with a thermally conductive material due to the reduced initial contact surface, which requires smaller compression force for assembly with the thermally conductive material. Preferably, the alternating non-concave surface portions collectively are in a substantially same imaginary plane to facilitate assembly of the heat sink with the thermally conductive material. Preferably, elongate grooves are fabricated to provide for a plurality of parallel bottoms that are in a substantially same imaginary plane.

The elongate concave surface portions may have any suitable cross-sectional profiles. Exemplary cross-sectional profiles include a curve, an arc, a square, a rectangle, a trapezoid, or any other regular or irregular shape.

The heat sink is preferably made from a material having good heat conductivity. Exemplary materials suitable for making the heat sinks of this disclosure comprises copper, brass, steel, aluminum, or their alloys. Other more expensive thermally conductive materials such as diamond may also be used for some applications.

In some embodiments, provided is an assembly that comprises a heat generating device, a heat sink, and a thermally conductive material between the heat generating device and the heat sink. The heat generating device may be electronic, optical, electro-optical, electro-mechanical, or any other type of heat generating devices that can benefit from the heat sink of this disclosure. For example, the heat generating device may be electronic circuits comprising a plurality of devices or components mounted on a printed circuit board.

The heat sink may be a stand-alone member which may be placed over the heat generating device to absorb and dissipate heat from the heat generating device. Alternatively, the heat sink may be an integral part of a housing that encloses the assembly and other devices. The housing is designed such that the integral heat sink may be placed over the heat generating device after assembly. Advantageously, the heat sink is designed to have a scalloped surface that is configured to interface the thermally conductive material. The scalloped surface may include a plurality of non-concave surface portions, which are designed to facilitate initial compression for assembly of the heat sink, the thermally conductive material, and the heat generating device. The scalloped surface includes a plurality of concave surface portions, which allow the thermally conductive material to flow over during assembly.

In some embodiments, provided is a method of assembling a heat sink with a heat generating device. In the method, a heat sink comprising a scalloped surface is provided. The scalloped surface has a plurality of concave surface portions and a plurality of non-concave surface portions. A heat generating device which may benefit from the heat sink is also provided. A thermally conductive material in a suitable form such as a thermal pad or foam is placed on the scalloped surface of the heat sink. Alternatively, the thermally conductive material may be placed over the heat generating device. A force is applied to the thermally conductive material e.g. by compressing the heat sink against the heat generating device. Because of the scalloped surface profile, the thermally conductive material is initially only in contact with the non-concave surface portions of the scalloped surface. The reduced contact surface area allows the use of reduced compression force in bringing the heat sink and heat generating device together through the thermally conductive material, which helps reduce the risk of damages to the heat generating devices due to excessive force. The compression force may be maintained to allow the thermally conductive material to flow over and in contact with the concave surface portions of the scalloped surface. The assembly can be secured using any suitable mean such as screws, clips, tapes etc.

Exemplary embodiments are now described with reference to the figures. It should be noted that some figures are not drawn to scale, and are only intended to facilitate the description of specific embodiments. They are not intended as an exhaustive description or as a limitation on the scope of the invention.

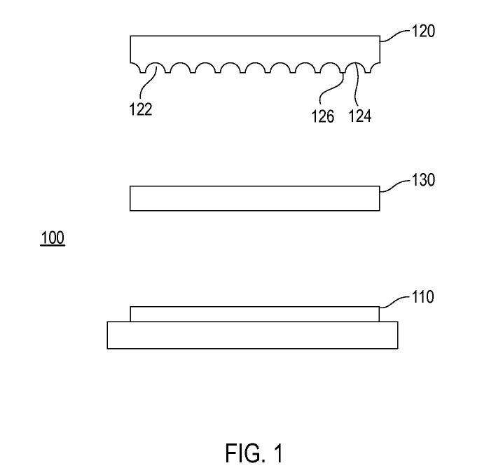

FIG. 1 is a schematic representation of an assembly 100 in accordance with some embodiments of the disclosure. The assembly 100 includes a heat generating device 110, a heat sink 120, and a thermally conductive material 130 between the heat generating device 110 and the heat sink 120. The heat generating device 110 may virtually be any type of heat generating devices that can benefit from the heat sink of this disclosure. By way of example, the heat generating device 110 may include a semiconductor chip mounted on a substrate, which in turn can be mounted on a printed circuit board. The printed circuit board may be a circuit card, a motherboard, or any other type of printed wiring board, which in turn may be a part of a larger system such as an X-ray imager, an X-ray tube, a computer, or any other electronic, optical, electro-optical, or electro-mechanical systems. The heat generating device 110 may also be a computer processor, a memory device, or an integrated circuit. Therefore, the heat generating device 110 may be a single component device, a device consisting of a group of components on a substrate, or a device consisting of a group of semiconductor chips and components mounted on a printed circuit board. The heat sink 120 provided by this disclosure can be readily scaled to benefit any kind of these and other heat generating devices 110.

The thermally conductive material 130 serves as an interface between the heat generating device 110 and the heat sink 120. The thermally conductive materials 110 may fill the gaps that may exist between the heat sink 120 and heat generating device 110 and provide effective thermal path between the heat generating device 110 and the heat sink 120.

Various thermally conductive materials 130 are known and commercially available, and therefore the detail description of their constructions is not described herein. In general, the thermally conductive materials 130 that can be used in this disclosure may be in various forms such as thermal pads, thermal foams, thermal grease, phase change material etc., depending on the applications. By way of example, the thermally conductive material 130 may be in the form of a thermal pad for use with the heat sink 120 of this disclosure in an exemplary application for transferring heat from an integrated circuit on a printed circuit board. The thermal pads 130 may have a tack on a side, which may be placed on the heat sink or on the heat generating device when in use. The thermal pads 110 may also have tack on both sides. The thermal pad 130 may be silicone based or acrylic based, which generally contain a base material and fillers added in the base material to increase the thermal conductivity. The thermal pad 130 may be soft or firm or dense. The softness or conformability of the thermal pad 130 can be configured based on application requirements such as gap filling, low assembled compression etc. When in use with the heat sink 120 of this disclosure, the thermal pad 130 may flow when being compressed, acting somewhat like a fluid.

The heat sink 120 may be made from a material that has good heat conductivity. By way of example, the heat sink 120 can be made from a material comprising copper, brass, steel, aluminum, diamond, graphite, or their alloys, etc. The heat sink 120 may be placed over the heat generating device 110 via the thermally conductive interface material 130. The size of the heat sink 120 can be readily scaled based on the outer surface or package of the heat generating device 110. For example, the size of heat sink 120 may be approximate or greater than the outer surface of the heat generating device 110 to adequately absorb and dissipate heat from the heat generating device.

The heat sink 120 preferably has a scalloped surface to facilitate interface to the thermally conductive material 130 or facilitate assembly of the heat sink 10 with the heat generating device 110. For example, a surface of the heat sink 120 may have a plurality of recesses 122, providing for a plurality of concave surface portions 124 over the recesses 122, and a plurality of non-concave surface portions 126 connecting adjacent concave surface portions 126. The provision of a plurality of concave surface portions 124 reduces the contact surface area initially for assembly with the thermally conductive interface material 130, and as a result, the compression force required for bringing together the heat sink 120 and the thermally conductive interface material 130 can be reduced. The provision of a plurality of concave surface portions 124 also increases the overall contact surface area with the thermally conductive interface material 130 once the assembly of the heat generating device 110, the thermally conductive interface material 130, and the heat sink 120 is complete. As a result, the heat transfer capacities of the heat sink 120 can be enhanced.

The plurality of recesses 122 may be elongate grooves substantially in parallel, providing for a plurality of elongate non-concave surface portions 126 alternating with a plurality of elongate concave surface portions 124. The individual elongate non-concave surface portions 126 may be narrow, or may be proximate one-dimensional thin strips or lines as compared to the elongate concave surface portions 124. Preferably, the non-concave surface portions 126, which alternate with concave surface portions 124, collectively are in a substantially same imaginary plane to facilitate assembly of the heat sink 120 with the thermally conductive material 130. Likewise, the elongate grooves 122 can be fabricated to provide for a plurality of parallel bottoms that collectively are in a substantially same imaginary plane. The individual elongate concave surface portions 124 may have a suitable cross-sectional profile. Exemplary cross-sectional profiles include a curve, an arc, a square, a rectangle, a trapezoid, or any other regular or irregular shape.

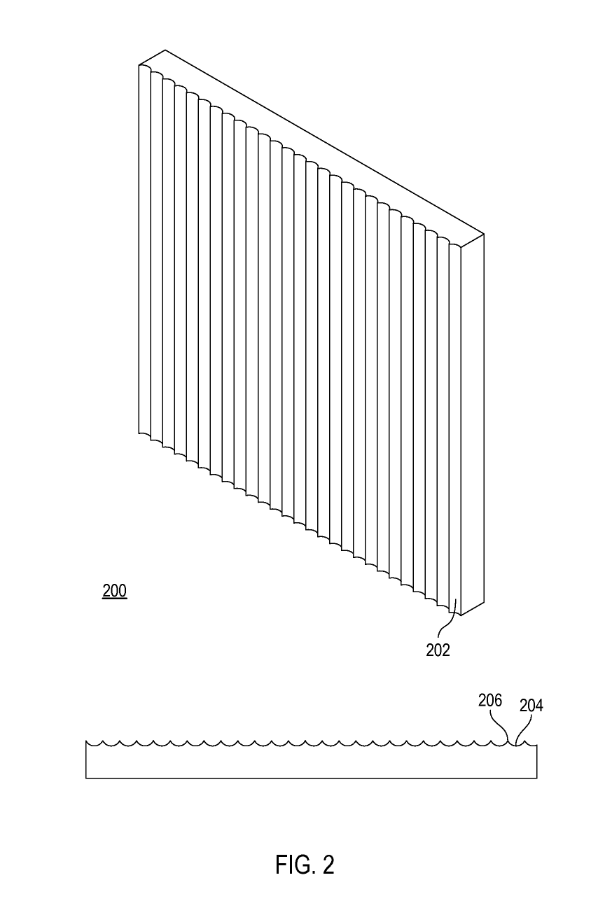

FIG. 2 illustrates an exemplary scalloped surface profile of a heat sink 200 in a perspective and a cross-sectional view in accordance with some embodiments of the disclosure. As shown, a plurality of elongate grooves 202 having an arc cross-sectional profile may be formed on a surface of the heat sink 200. These elongate, parallel grooves 202 provide for a plurality of concave surface portions 204 alternating with a plurality of non-concave surface portions 206. While the plurality of individual non-concave surface portions 206 are shown as one-dimensional lines, non-concave surface portions 206 in narrow strips having a width comparable with that of the concave surface portions 204 are possible and contemplated by the inventors.

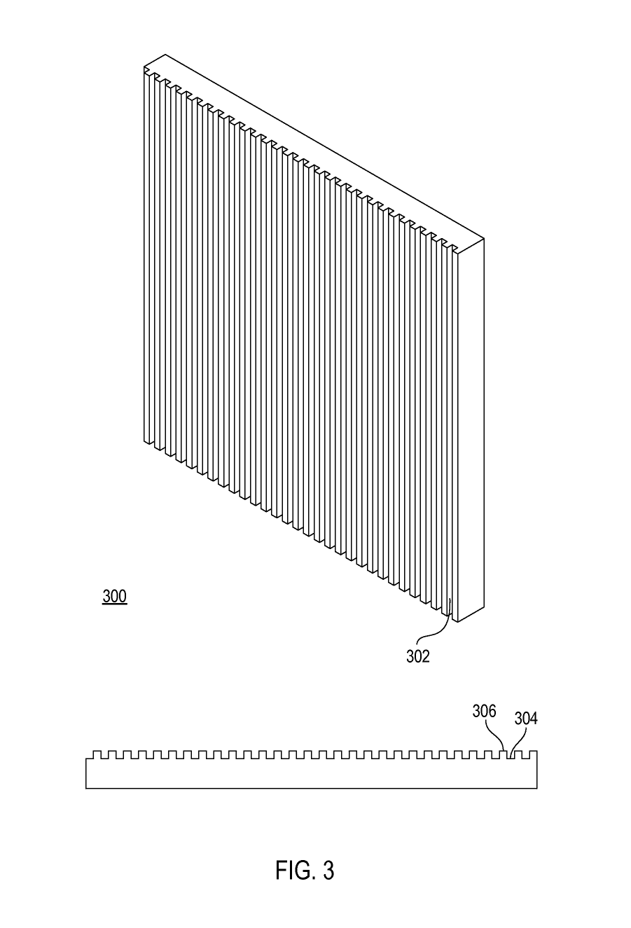

FIG. 3 illustrates another exemplary scalloped surface profile of a heat sink 300 in a perspective and a cross-sectional view in accordance with some embodiments of the disclosure. As shown, a plurality of elongate grooves 302 having a square or rectangular cross-sectional profile may be formed on a surface of the heat sink 300. These elongate, parallel grooves 302 provide for a plurality of concave surface portions 304 alternating with a plurality of non-concave surface portions 306. As shown, the non-concave surface portions 306 collectively are in a substantially same imaginary plane. Likewise, the bottoms of the concave surface portions 304 collectively may be in a substantially same imaginary plane.

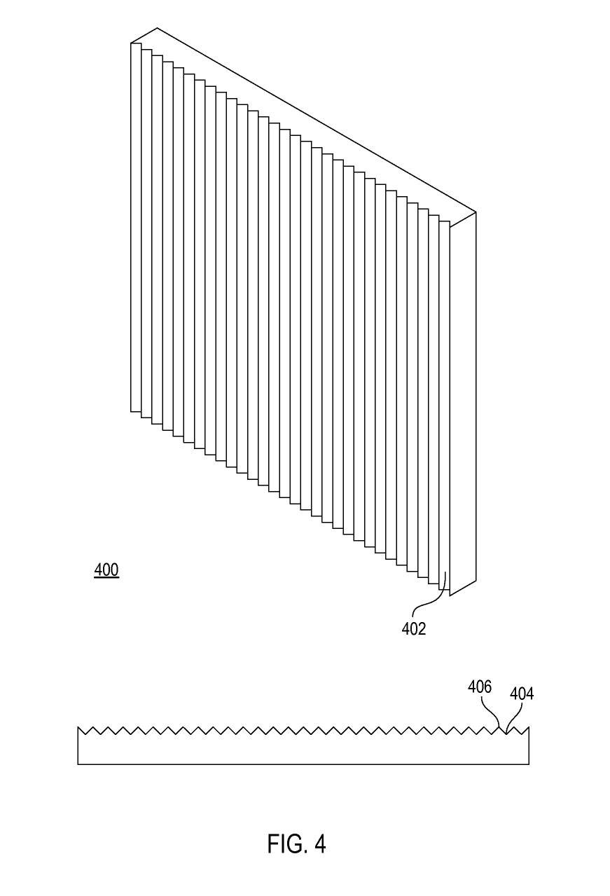

FIG. 4 illustrates a further exemplary scalloped surface profile of a heat sink 400 in a perspective and a cross-sectional view in accordance with some embodiments of the disclosure. As shown, a plurality of elongate grooves 402 having a triangular cross-sectional profile may be formed on a surface of the heat sink 400. These elongate, parallel grooves 402 provide for a plurality of concave surface portions 404 alternating with a plurality of non-concave surface portions 406. While the plurality of individual non-concave surface portions 406 are shown as one-dimensional lines, non-concave surface portions 406 in narrow strips having a width comparable with that of the concave surface portions 404 are possible and contemplated by the inventors.

The heat sinks described in this disclosure can be readily manufactured according to the techniques and from the materials that are known in the art. Suitable techniques that can be used to fabricate the heat sinks having a scalloped surface profile include but are not limited to casting, machining, electronic discharge machining, etching etc. Other techniques known and available to those skilled in the art can also be used. Materials that can be used in making the heat sink include but are not limited to copper, brass, steel, aluminum, diamond, graphite, or their alloys, etc.

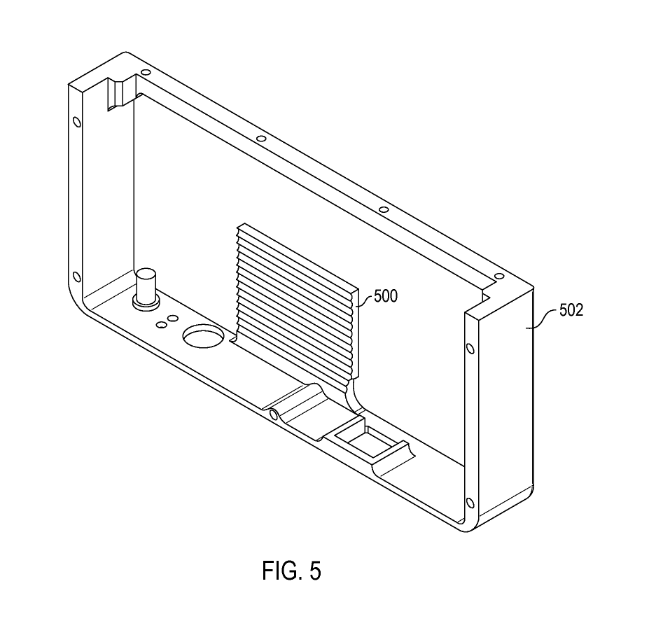

FIG. 5 illustrates a further exemplary heat sink 500 in accordance with some embodiments of the disclosure. As shown, the heat sink 500 may be an integral part of an enclosure 502 that houses a heat generating device (not shown) such as a circuit board including a plurality of electronic components or devices. The enclosure 502 may also house a larger system of which the heat generating device is only part of the system. Once the system including the heat generating device such as an integrated circuit on a circuit board is installed, the enclosure 502 can then be placed over system and secured. The enclosure 502 can be designed such that the integral heat sink 500 may sit over the heat generating device once assembly is completed. The thermally conductive material such as a thermal pad (not shown) may have a tacky side, which can be placed on either the heat sink 500 or the heat generating device before assembly. Alternatively, the thermal pad may have tack on both sides to facilitate securing to the heat generating device and heat sink.

Heat sinks with scalloped surface profiles have been described. Those skilled in the art will appreciate that various other modifications may be made within the spirit and scope of the disclosure. All these or other variations and modifications are contemplated by the inventors and within the scope of the disclosure.

What is claimed is:

1. A heat sink comprising a surface adapted to interface a thermally conductive material, wherein the surface comprises one or more concave surface portions and one or more non-concave surface portions.

2. The heat sink of claim 1 wherein the surface comprises a plurality of elongate recesses substantially in parallel, providing for a plurality of concave surface portions over the recesses and a plurality of non-concave surface portions alternating with the plurality of concave surface portions.

3. The heat sink of claim 2 wherein at least some of the non-concave surface portions collectively are in a substantially same imaginary plane.

4. The heat sink of claim 2 wherein at least some of the plurality of concave surface portions have a cross-sectional shape of an arc.

5. The heat sink of claim 2 wherein at least some of the plurality of concave surface portions have a cross-sectional shape of a square or rectangle.

6. The heat sink of claim 2 wherein at least some of the plurality of concave surface portions have a cross-sectional shape of a triangle.

7. The heat sink of claim 2 wherein at least some of the plurality of concave surface portions have a cross-sectional shape of a trapezoid.

8. The heat sink of claim 1 wherein said base member is made from a material comprising copper, brass, steel, aluminum, diamond, graphite, or their alloys.

9. An assembly comprising:
a heat generating device;
a heat sink; and
a thermally conductive material between the heat generating device and the heat sink;
wherein the heat sink comprises a surface interfacing the thermally conductive material, and the surface comprises one or more concave surface portions and one or more non-concave surface portions.

10. The assembly of claim 9 further comprising an enclosure enclosing the heat generating device, the heat sink, and the thermally conductive material, wherein the heat sink is integral with the enclosure.

11. The assembly of claim 9 wherein the surface comprises a plurality of elongate recesses substantially in parallel, providing for a plurality of concave surface portions over the recesses and a plurality of non-concave surface portions alternating with the plurality of concave surface portions.

12. The assembly of claim 11 wherein at least some of the plurality of concave surface portions have a cross-sectional shape of an arc.

13. The assembly of claim 11 wherein at least some of the plurality of concave surface portions have a cross-sectional shape of a square or rectangle.

14. The assembly of claim 11 wherein at least some of the plurality of concave surface portions have a cross-sectional shape of a triangle.

15. The assembly of claim 11 wherein at least some of the plurality of concave surface portions have a cross-sectional shape of a trapezoid.

16. The assembly of claim 11 wherein the heat sink is made from a material comprising copper, brass, steel, aluminum, diamond, graphite, or their alloys.

17. The assembly of claim 9 wherein the thermally conductive material is in the form of a conformable pad.

18. The assembly of claim 9 wherein the heat generating device comprises an integrated circuit on a printed circuit board.

19. A method of assembling a heat sink with a heat generating device comprising:
providing a heat sink comprising a surface having one or more concave surface portions and one or more non-concave surface portions;
providing a heat generating device and a thermally conductive material configured to interface the heat sink and the heat generating device;
placing the thermally conductive material between the heat generating device and the heat sink and bring the thermally conductive material in contact with the non-concave surface portions of the heat sink; and
applying a compression force between the heat sink and the heat generating device to bring the thermally conductive material in contact with the concave surface portions of the surface.

20. The method of claim 19 wherein
the surface comprises a plurality of elongate recesses substantially in parallel, providing for the one or more concave surface portions over the recesses and the one or more non-concave surface portions alternating with the one or more concave surface portions,
the thermally conductive material is in the form of a conformable pad; and
the compression force applied is sufficient to allow the thermally conductive material to flow into and fill the plurality of the recesses.
